(19) United States
(12) Patent Application Publication
(10) Pub. No.: US 2026/0362936 A1
(43) Pub. Date: Nov. 12, 2026

(54) DISPLAY DEVICE AND ELECTRONIC DEVICE INCLUDING THE SAME

(71) Applicant: Samsung Display Co., Ltd., Yongin-Si (KR)

(72) Inventors: SUJUNG HUH, Yongin-si (KR); RANGKYUN MOK, Yongin-si (KR); Abe Koichi, Yongin-si (KR); DAE-YOUNG LEE, Yongin-si (KR)

(21) Appl. No.: 19/578,940

(22) Filed: Mar. 26, 2026

(30) Foreign Application Priority Data
May 9, 2025 (KR) 10-2025-0060099

(51) Int. Cl. H10K 59/50; G02F 1/1335; H10K 59/122

(52) U.S. Cl. CPC H10K 59/50; G02F 1/133512; G02F 1/133533; G02F 1/133541; H10K 59/122

(57) ABSTRACT

A display device includes a substrate including emission areas and a non-emission area surrounding the emission areas and narrow viewing angle pixels and general pixels arranged in the emission areas. Each of the narrow viewing angle pixels includes a light-emitting layer arranged on the substrate and arranged in a pixel opening defined in a pixel defining layer, a common electrode arranged on the light-emitting layer, a cholesteric liquid crystal layer including a chiral dopant and overlapping the light-emitting layer, a light blocking pattern overlapping the pixel defining layer, and a polarizer arranged on the cholesteric liquid crystal layer.

### CROSS-REFERENCE TO RELATED APPLICATION

The present application claims priority to and the benefit of Korean Patent Application No. 10-2025-0060099 filed on May 9, 2025 in the Korean Intellectual Property Office, which is incorporated herein by reference.

### BACKGROUND

### 1. Field

Embodiments relate to a display device and an electronic device including the display device. More specifically, embodiments relate to a display device which provides visual information and an electronic device including the display device.

### 2. Description of the Related Art

There is an increasing demand for a display device that allows a user to control a viewing angle of an image as needed. The display device capable of viewing angle adjustment may be a display device in which, in case that the user operates the display device in a general mode, the image is displayed with a wide viewing angle, and in case that the user operates the display device in a private mode, the image is displayed with a narrow viewing angle.

### SUMMARY

Embodiments provide a display device in which light efficiency is improved.

Embodiments provide an electronic device including the display device.

A display device according to an embodiment includes a substrate including emission areas and a non-emission area surrounding the emission areas and narrow viewing angle pixels and general pixels arranged in the emission areas. Each of the narrow viewing angle pixels includes a light-emitting layer arranged on the substrate and arranged in a pixel opening defined in a pixel defining layer, a common electrode arranged on the light-emitting layer, a cholesteric liquid crystal layer including a chiral dopant and overlapping the light-emitting layer, a light blocking pattern overlapping the pixel defining layer, and a polarizer arranged on the cholesteric liquid crystal layer.

In an embodiment, the light blocking pattern may be arranged in a layer between the cholesteric liquid crystal layer and a cover window.

In an embodiment, the light blocking pattern may be arranged in a layer between the cholesteric liquid crystal layer and the light-emitting layer.

In an embodiment, the light blocking pattern may include a first light blocking pattern arranged on the common electrode, and a second light blocking pattern arranged on the first light blocking pattern. The cholesteric liquid crystal layer may be arranged between a first layer including the first light blocking pattern and a second layer including the second light blocking pattern.

In an embodiment, the light-emitting layer may include a first light-emitting layer that emits red light, a second light-emitting layer that emits green light, and a third light-emitting layer that emits blue light. The cholesteric liquid crystal layer may include a first cholesteric liquid crystal layer overlapping the first light-emitting layer in a plan view, a second cholesteric liquid crystal layer overlapping the second light-emitting layer in a plan view, and a third cholesteric liquid crystal layer overlapping the third light-emitting layer in a plan view. The first cholesteric liquid crystal layer may selectively reflect either right-handed circularly polarized red light or left-handed circularly polarized red light. The second cholesteric liquid crystal layer may selectively reflect either right-handed circularly polarized green light or left-handed circularly polarized green light. The third cholesteric liquid crystal layer may selectively reflect either right-handed circularly polarized blue light or left-handed circularly polarized blue light.

In an embodiment, the common electrode may change a phase of light that is reflected from the cholesteric liquid crystal layer so that the light passes through the polarizer.

In an embodiment, the polarizer may include a phase difference plate arranged on the cholesteric liquid crystal layer and a linear polarizer arranged on the phase difference plate.

In an embodiment, the phase difference plate may be a quarter wave plate.

In an embodiment, each of the narrow viewing angle pixels may further include a first electrode arranged under the cholesteric liquid crystal layer and contacting the cholesteric liquid crystal layer and a second electrode arranged on the cholesteric liquid crystal layer and contacting the cholesteric liquid crystal layer.

In an embodiment, the first electrode and the second electrode may include a transparent conductive material.

In an embodiment, the general pixels may be spaced apart from the narrow viewing angle pixels. Center points of the general pixels may be respectively arranged at vertices of a virtual rectangle centered at a center point of the narrow viewing angle pixel.

In an embodiment, each of the general pixels may include a light-emitting layer arranged on the substrate and arranged in the pixel opening defined in the pixel defining layer, the common electrode arranged on the light-emitting layer, and the polarizer arranged on the common electrode.

In an embodiment, each of the general pixels may further include the cholesteric liquid crystal layer including the chiral dopant arranged on the common electrode and overlapping the light-emitting layer in a plan view.

In an embodiment, each of the general pixels may further include a first electrode arranged under the cholesteric liquid crystal layer and contacting the cholesteric liquid crystal layer and a second electrode arranged on the cholesteric liquid crystal layer and contacting the cholesteric liquid crystal layer.

An electronic device according to an embodiment includes a display device and a processor which controls the display device. The display device includes a substrate including emission areas and a non-emission area surrounding the emission areas and narrow viewing angle pixels and general pixels arranged in the emission areas. Each of the narrow viewing angle pixels includes a light-emitting layer arranged on the substrate and arranged in a pixel opening defined in a pixel defining layer, a common electrode arranged on the light-emitting layer, a cholesteric liquid crystal layer including a chiral dopant and overlapping the light-emitting layer, a light blocking pattern overlapping the pixel defining layer, a polarizer arranged on the cholesteric liquid crystal layer, and a process that controls the display device.

In an embodiment, the light blocking pattern may be arranged in a layer between the cholesteric liquid crystal layer and a cover window.

In an embodiment, the light blocking pattern may be arranged in a layer between the cholesteric liquid crystal layer and the light-emitting layer.

In an embodiment, the light blocking pattern may include a first light blocking pattern arranged on the common electrode and a second light blocking pattern arranged on the first light blocking pattern. The cholesteric liquid crystal layer may be arranged between a first layer including the first light blocking pattern and a second layer including the second light blocking pattern.

In an embodiment, each of the narrow viewing angle pixels may further include a first electrode arranged under the cholesteric liquid crystal layer and contacting the cholesteric liquid crystal layer and a second electrode arranged on the cholesteric liquid crystal layer and contacting the cholesteric liquid crystal layer.

In an embodiment, the first electrode and the second electrode may include a transparent conductive material.

A display device according to embodiments may be driven in a general mode and a private mode, and may include general pixel and narrow viewing angle pixel. The narrow viewing angle pixel may include a cholesteric liquid crystal layer including a chiral dopant. The cholesteric liquid crystal layer may selectively reflect either right-handed circularly polarized light or left-handed circularly polarized light emitted from a light-emitting layer. The selectively reflected light may be re-reflected by a common electrode so that a phase of the light is changed and the light may pass through a polarizer. Accordingly, light efficiency in the private mode may be improved.

The narrow viewing angle pixel may further include a first electrode arranged under the cholesteric liquid crystal layer and directly contacting the cholesteric liquid crystal layer and a second electrode arranged on the cholesteric liquid crystal layer and directly contacting the cholesteric liquid crystal layer. In case that there is a voltage difference between the first electrode and the second electrode, the light efficiency in the private mode may be improved by controlling the selective reflection of the cholesteric liquid crystal layer.

The general pixel may also include the cholesteric liquid crystal layer including the chiral dopant, as in the narrow viewing angle pixel. In addition, the general pixel may further include the first electrode arranged under the cholesteric liquid crystal layer and directly contacting the cholesteric liquid crystal layer and the second electrode arranged on the cholesteric liquid crystal layer and directly contacting the cholesteric liquid crystal layer.

Accordingly, light efficiency in the general mode may also be improved.

It is to be understood that both the foregoing general description and the following detailed description are illustrative and explanatory and are intended to provide further explanation of the invention to those skilled in the art.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to an embodiment.

FIG. 2 is an enlarged plan view of an area A of FIG. 1.

FIG. 3 is a cross-sectional view illustrating an embodiment of narrow viewing angle pixels included in the display device of FIG. 2.

FIG. 4 is a view illustrating a movement path of light in the display device according to an embodiment.

FIG. 5 is a view illustrating a luminance improvement effect of the display device according to an embodiment.

FIG. 6 is a view illustrating a transmittance improvement effect of the display device according to an embodiment.

FIG. 7 is a view illustrating a luminance improvement effect of the display device according to an embodiment.

FIG. 8 is a cross-sectional view illustrating another embodiment of the narrow viewing angle pixels included in the display device of FIG. 2.

FIG. 9 is a cross-sectional view illustrating still another embodiment of the narrow viewing angle pixels included in the display device of FIG. 2.

FIGS. 10 to 12 are cross-sectional views illustrating yet another embodiment of the narrow viewing angle pixels included in the display device of FIG. 2.

FIG. 13 is a cross-sectional view illustrating one embodiment of general pixels included in the display device of FIG. 2.

FIG. 14 is a cross-sectional view illustrating another embodiment of the general pixels included in the display device of FIG. 2.

FIG. 15 is a cross-sectional view illustrating still another embodiment of the general pixels included in the display device of FIG. 2.

FIG. 16 is a block diagram of an electronic device according to an embodiment.

FIG. 17 illustrates schematic diagrams of electronic devices according to various embodiments.

### DETAILED DESCRIPTION OF THE EMBODIMENTS

Hereinafter, embodiments will be described in more detail with reference to the accompanying drawings. In the accompanying drawings, the same reference numerals are used for the same components, and redundant descriptions of the same components will be omitted.

In this specification, a plane may be defined by a first direction DR1 and a second direction DR2 intersecting the first direction DR1. For example, the second direction DR2 may be perpendicular to the first direction DR1. In addition, a third direction DR3 may be a direction that is normal to the plane. That is, the third direction DR3 may be perpendicular to the plane defined by the first direction DR1 and the second direction DR2.

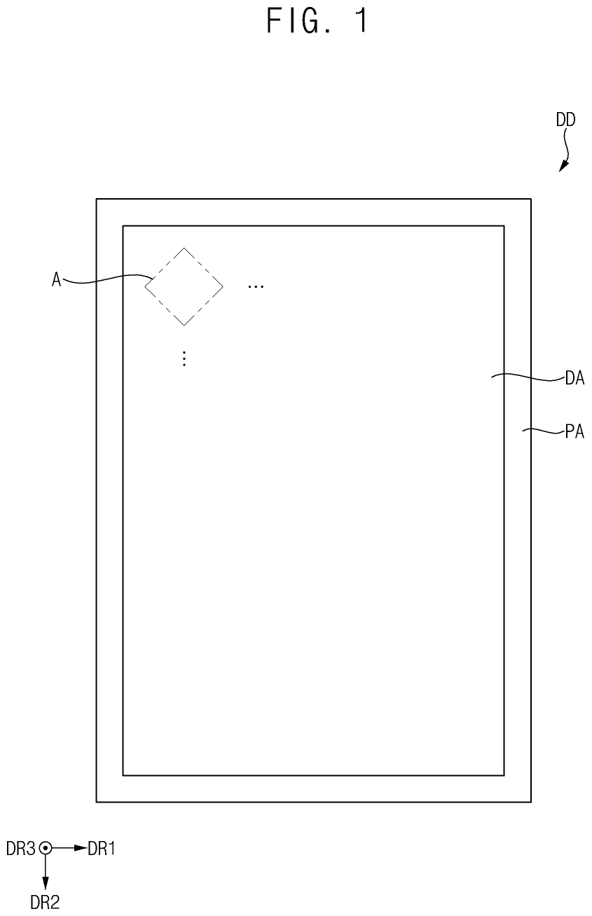

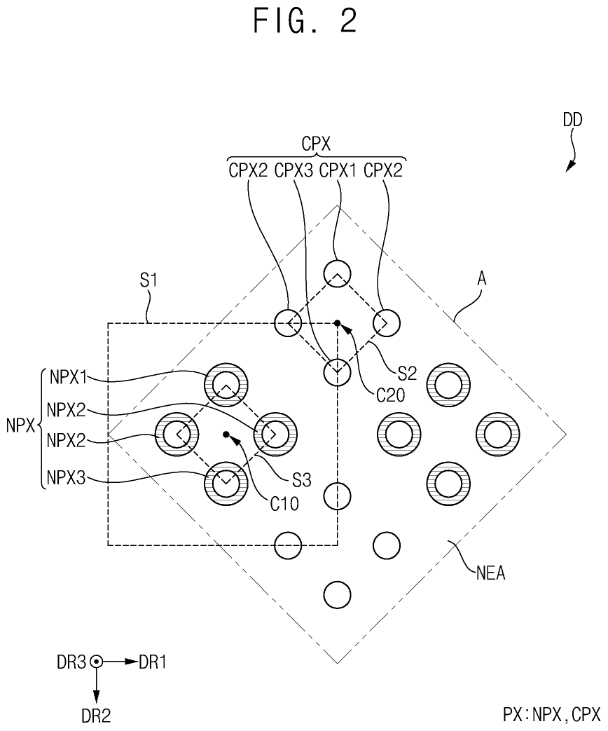

FIG. 1 is a plan view illustrating a display device according to an embodiment. FIG. 2 is an enlarged plan view of an area A of FIG. 1.

Referring to FIGS. 1 and 2, a display device DD may include a display area DA and a peripheral area PA. The display area DA may be an area which displays an image by generating light or by controlling transmittance of light provided from an external light source. The peripheral area PA may be located around the display area DA. For example, in a plan view, the peripheral area PA may surround at least a portion of the display area DA. In an embodiment, the peripheral area PA may be an area which does not display the image. However, embodiments are not necessarily limited thereto. For example, the image may be displayed in at least a portion of the peripheral area PA.

The display area DA may include a plurality of pixels PX and a non-emission area NEA.

The plurality of pixels PX may include general pixels CPX and narrow viewing angle pixels NPX. The display device DD may allow a user to control a viewing angle of the image as needed. For example, the display device DD may be driven in a general mode and a private mode. In the general mode, both the general pixels CPX and the narrow viewing angle pixels NPX may emit light, or the narrow viewing angle pixels NPX may not emit light and only the general pixels CPX may emit light. In the private mode, the general pixels CPX may not emit light and only the narrow viewing angle pixels NPX may emit light.

The general pixels CPX and the narrow viewing angle pixels NPX may be repeatedly arranged in a plan view. The general pixels CPX may be spaced apart from the narrow viewing angle pixels NPX. In an embodiment, a center point C20 of the general pixel CPX may be arranged at one of the vertices of a virtual rectangle S1 centered at a center point C10 of the narrow viewing angle pixel NPX in a plan view.

The general pixel CPX may include a first general pixel CPX1, at least one second general pixel CPX2, and a third general pixel CPX3. The first to third general pixels CPX1, CPX2, and CPX3 may be spaced apart from one another. In an embodiment, the first to third general pixels CPX1, CPX2, and CPX3 may be respectively arranged at vertices of a virtual rectangle S2 in a plan view. The general pixel CPX may include a plurality of the second general pixels CPX2, which may be positioned at diagonally opposite corners of the rectangle S2. The plurality of the second general pixels CPX2 may have the same shape as one another. The plurality of the second general pixels CPX2 may be arranged to be spaced apart from one another in the first direction DR1.

The narrow viewing angle pixel NPX may include a first narrow viewing angle pixel NPX1, at least one second narrow viewing angle pixel NPX2, and a third narrow viewing angle pixel NPX3. The first to third narrow viewing angle pixels NPX1, NPX2, and NPX3 may be spaced apart from one another. In an embodiment, the first to third narrow viewing angle pixels NPX1, NPX2, and NPX3 may be respectively arranged at vertices of a virtual rectangle S3 in a plan view. The narrow viewing angle pixel NPX may include a plurality of the second narrow viewing angle pixels NPX2. The plurality of the second narrow viewing angle pixels NPX2 may have the same shape as one another, and may be positioned at diagonally opposite corners of the rectangle S1. The plurality of the second narrow viewing angle pixels NPX2 may be arranged to be spaced apart from one another in the first direction DR1.

The first general pixel CPX1, the second general pixel CPX2, and the third general pixel CPX3 may have the same size as one another. However, embodiments are not necessarily limited thereto. For example, the first general pixel CPX1, the second general pixel CPX2, and the third general pixel CPX3 may have different sizes from one another.

Each of the first general pixel CPX1, the second general pixel CPX2, and the third general pixel CPX3 may have a rectangular planar shape, a circular planar shape, an elliptical planar shape, or the like. In an embodiment, each of the first general pixel CPX1, the second general pixel CPX2, and the third general pixel CPX3 may have a circular planar shape. However, embodiments are not necessarily limited thereto.

The first narrow viewing angle pixel NPX1, the second narrow viewing angle pixel NPX2, and the third narrow viewing angle pixel NPX3 may have the same size as one another. However, embodiments are not necessarily limited thereto. For example, the first narrow viewing angle pixel NPX1, the second narrow viewing angle pixel NPX2, and the third narrow viewing angle pixel NPX3 may have different sizes from one another.

Each of the first narrow viewing angle pixel NPX1, the second narrow viewing angle pixel NPX2, and the third narrow viewing angle pixel NPX3 may have a rectangular planar shape, a circular planar shape, an elliptical planar shape, or the like. In an embodiment, each of the first narrow viewing angle pixel NPX1, the second narrow viewing angle pixel NPX2, and the third narrow viewing angle pixel NPX3 may have a circular planar shape. However, embodiments are not necessarily limited thereto.

In an embodiment, the first general pixel CPX1 may emit red light, the second general pixel CPX2 may emit green light, and the third general pixel CPX3 may emit blue light. However, embodiments are not necessarily limited thereto.

In an embodiment, the first narrow viewing angle pixel NPX1 may emit red light, the second narrow viewing angle pixel NPX2 may emit green light, and the third narrow viewing angle pixel NPX3 may emit blue light. However, embodiments are not necessarily limited thereto.

The non-emission area NEA may surround the general pixels CPX and the narrow viewing angle pixels NPX in a plan view. For example, the non-emission area NEA may have a grid shape in a plan view. The non-emission area NEA may not emit light. However, embodiments are not necessarily limited thereto.

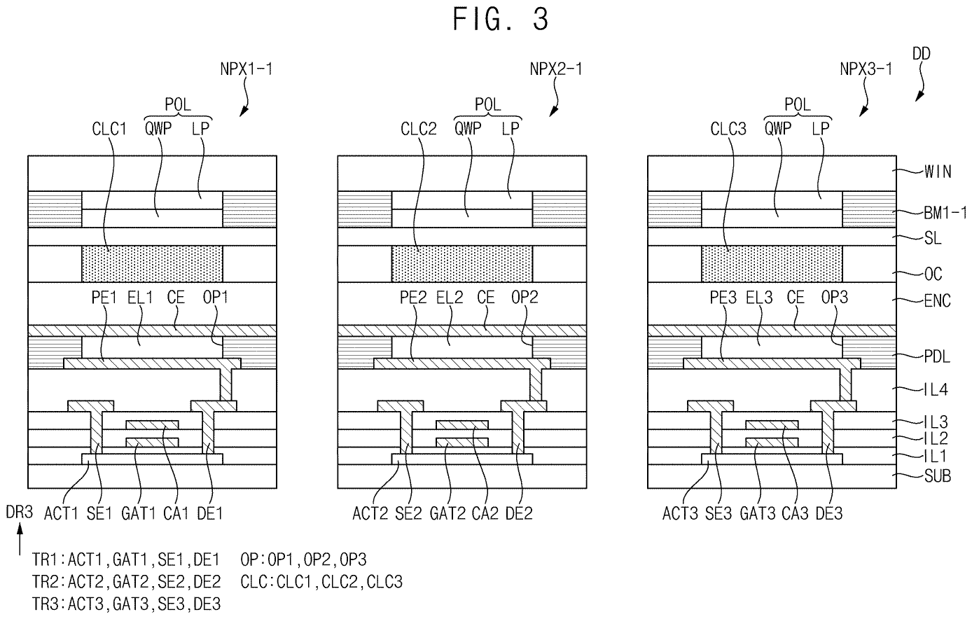

FIG. 3 is a cross-sectional view illustrating an embodiment of narrow viewing angle pixels included in the display device of FIG. 2.

Referring to FIG. 3, the display device DD may include a 1-1 narrow viewing angle pixel NPX1-1, a 2-1 narrow viewing angle pixel NPX2-1, and a 3-1 narrow viewing angle pixel NPX3-1. The display device DD may include a substrate SUB, a first transistor TR1, a second transistor TR2, a third transistor TR3, a first capacitor electrode CA1, a second capacitor electrode CA2, a third capacitor electrode CA3, a first insulating layer IL1, a second insulating layer IL2, a third insulating layer IL3, a fourth insulating layer IL4, a first pixel electrode PE1, a second pixel electrode PE2, a third pixel electrode PE3, a first light-emitting layer EL1, a second light-emitting layer EL2, a third light-emitting layer EL3, a common electrode CE, an encapsulation layer ENC, an overcoat layer OC, a first cholesteric liquid crystal layer CLC1, a second cholesteric liquid crystal layer CLC2, a third cholesteric liquid crystal layer CLC3, a sensing layer SL, a 1-1 light blocking pattern BM1-1, a polarizer POL, and a cover window WIN.

The first transistor TR1 may include a first active pattern ACT1, a first gate electrode GAT1, a first source electrode SE1, and a first drain electrode DE1. The second transistor TR2 may include a second active pattern ACT2, a second gate electrode GAT2, a second source electrode SE2, and a second drain electrode DE2. The third transistor TR3 may include a third active pattern ACT3, a third gate electrode GAT3, a third source electrode SE3, and a third drain electrode DE3.

The substrate SUB may include a transparent material or an opaque material. In an embodiment, the substrate SUB may include glass, quartz, silicon, plastic, or the like. Examples of the plastic which may be used in the substrate SUB may include polyimide PI, polypropylene PP, polycarbonate PC, polystyrene PS, and/or the like. These may be used alone or in combination with each other.

The first active pattern ACT1 may be arranged on the substrate SUB. In an embodiment, the first active pattern ACT1 may include a silicon semiconductor. For example, the first active pattern ACT1 may include amorphous silicon, polycrystalline silicon, or the like. In an embodiment, the first active pattern ACT1 may include an oxide semiconductor.

The second active pattern ACT2 and the third active pattern ACT3 may be formed together with the first active pattern ACT1. That is, the second active pattern ACT2 and the third active pattern ACT3 may include the same material as the first active pattern ACT1.

The first insulating layer IL1 may cover the first to third active patterns ACT1, ACT2, and ACT3 and may be arranged on the substrate SUB. In an embodiment, the first insulating layer IL1 may include an inorganic insulating material. For example, the first insulating layer IL1 may include silicon oxide (SiOₓ), silicon nitride (SiNₓ), silicon oxynitride (SiOₓN_{y}), and/or the like. These may be used alone or in combination with each other.

The first gate electrode GAT1 may be arranged on the first insulating layer IL1. The first gate electrode GAT1 may overlap the first active pattern ACT1 in a plan view. In an embodiment, the first gate electrode GAT1 may include a metal, an alloy, a conductive metal oxide, a transparent conductive material, and/or the like. For example, the first gate electrode GAT1 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), and/or the like. These may be used alone or in combination with each other. In addition, the first gate electrode GAT1 may be formed as a single layer or as multiple layers.

The second gate electrode GAT2 and the third gate electrode GAT3 may be formed together with the first gate electrode GAT1. That is, the second gate electrode GAT2 and the third gate electrode GAT3 may include the same material as the first gate electrode GAT1. The second gate electrode GAT2 may overlap the second active pattern ACT2 in a plan view. The third gate electrode GAT3 may overlap the third active pattern ACT3 in a plan view.

The second insulating layer IL2 may cover the first to third gate electrodes GAT1, GAT2, and GAT3 and may be arranged on the first insulating layer IL1. In an embodiment, the second insulating layer IL2 may include an inorganic insulating material. For example, the second insulating layer IL2 may include silicon oxide, silicon nitride, silicon oxynitride, and/or the like. These may be used alone or in combination with each other.

The first capacitor electrode CA1 may be arranged on the second insulating layer IL2. The first capacitor electrode CA1 may overlap the first gate electrode GAT1 in a plan view. In an embodiment, the first capacitor electrode CA1 may include a metal, an alloy, a conductive metal oxide, a transparent conductive material, and/or the like. These may be used alone or in combination with each other. In addition, the first capacitor electrode CA1 may be formed as a single layer or as multiple layers.

The first capacitor electrode CA1 may be arranged on the second insulating layer IL2. The first capacitor electrode CA1 may overlap the first gate electrode GAT1 in a plan view. In an embodiment, the first capacitor electrode CA1 may include a metal, an alloy, a conductive metal oxide, a transparent conductive material, and/or the like. These may be used alone or in combination with each other. In addition, the first capacitor electrode CA1 may be formed as a single layer or as multiple layers.

The second capacitor electrode CA2 and the third capacitor electrode CA3 may be formed together with the first capacitor electrode CA1. That is, the second capacitor electrode CA2 and the third capacitor electrode CA3 may include the same material as the first capacitor electrode CA1. The second capacitor electrode CA2 may overlap the second gate electrode GAT2 in a plan view. The third capacitor electrode CA3 may overlap the third gate electrode GAT3 in a plan view.

The third insulating layer IL3 may cover the first to third capacitor electrodes CA1, CA2, and CA3 and may be arranged on the second insulating layer IL2. In an embodiment, the third insulating layer IL3 may include an inorganic insulating material. For example, the third insulating layer IL3 may include silicon oxide, silicon nitride, silicon oxynitride, and/or the like. These may be used alone or in combination with each other.

The first source electrode SE1 may be arranged on the third insulating layer IL3 and may contact the first active pattern ACT1. In an embodiment, the first source electrode SE1 may include a metal, an alloy, a conductive metal oxide, a transparent conductive material, and/or the like. These may be used alone or in combination with each other. In addition, the first source electrode SE1 may be formed as a single layer or as multiple layers.

The second source electrode SE2 and the third source electrode SE3 may be formed together with the first source electrode SE1. That is, the second source electrode SE2 and the third source electrode SE3 may include the same material as the first source electrode SE1. The second source electrode SE2 may contact the second active pattern ACT2. The third source electrode SE3 may contact the third active pattern ACT3.

The first drain electrode DE1 may be arranged on the third insulating layer IL3 and may contact the first active pattern ACT1. In an embodiment, the first drain electrode DE1 may include a metal, an alloy, a conductive metal oxide, a transparent conductive material, and/or the like. These may be used alone or in combination with each other. In addition, the first drain electrode DE1 may be formed as a single layer or as multiple layers.

The second drain electrode DE2 and the third drain electrode DE3 may be formed together with the first drain electrode DE1. That is, the second drain electrode DE2 and the third drain electrode DE3 may include the same material as the first drain electrode DE1. The second drain electrode DE2 may contact the second active pattern ACT2. The third drain electrode DE3 may contact the third active pattern ACT3.

The fourth insulating layer IL4 may cover the first to third source electrodes SE1, SE2, and SE3 and the first to third drain electrodes DE1, DE2, and DE3 and may be arranged on the third insulating layer IL3. In an embodiment, the fourth insulating layer IL4 may include an organic insulating material. For example, the fourth insulating layer IL4 may include photoresist, polyacrylic resin, polyimide resin, acrylic resin, and/or the like. These may be used alone or in combination with each other. In an embodiment, the fourth insulating layer IL4 may have a multi-layer structure including one or more organic insulating layers and one or more inorganic insulating layers.

The first pixel electrode PE1 may be arranged on the fourth insulating layer IL4 and may contact the first drain electrode DE1. In an embodiment, the first pixel electrode PE1 may include a metal, an alloy, a conductive metal oxide, a transparent conductive material, and/or the like. These may be used alone or in combination with each other. In addition, the first pixel electrode PE1 may be formed as a single layer or as multiple layers. For example, the first pixel electrode PE1 may be a reflective electrode.

The second pixel electrode PE2 and the third pixel electrode PE3 may be formed together with the first pixel electrode PE1. That is, the second pixel electrode PE2 and the third pixel electrode PE3 may include the same material as the first pixel electrode PE1. The second pixel electrode PE2 may contact the second drain electrode DE2. The third pixel electrode PE3 may contact the third drain electrode DE3.

The pixel defining layer PDL may be arranged on the fourth insulating layer IL4 and may cover an edge of the first pixel electrode PE1. A first pixel opening OP1, which is above at least a portion of the first pixel electrode PE1, may be defined in the pixel defining layer PDL. In an embodiment, the pixel defining layer PDL may include an organic insulating material. For example, the pixel defining layer PDL may include photoresist, polyacrylic resin, polyimide resin, acrylic resin, and/or the like. These may be used alone or in combination with each other. In an embodiment, the pixel defining layer PDL may further include a light blocking material having a black color.

The pixel defining layer PDL may cover an edge of the second pixel electrode PE2. A second pixel opening OP2, which is above at least a portion of the second pixel electrode PE2, may be defined in the pixel defining layer PDL. In addition, the pixel defining layer PDL may cover an edge of the third pixel electrode PE3. A third pixel opening OP3, which exposes at least a portion of the third pixel electrode PE3, may be defined in the pixel defining layer PDL.

Light-emitting layer EL may include the first light-emitting layer EL1, the second light-emitting layer EL2, and the third light-emitting layer EL3. The first light-emitting layer EL1 may be arranged on the first pixel electrode PE1. In an embodiment, the first light-emitting layer EL1 may include an organic light-emitting material which receives current and emits light. For example, the first light-emitting layer EL1 may include an organic light-emitting material which emits red light. The first light-emitting layer EL1 may emit light corresponding to a driving current. In addition, an auxiliary layer, such as a hole transport layer or an electron transport layer, may be further arranged under and/or on the first light-emitting layer EL1.

The second light-emitting layer EL2 may be arranged on the second pixel electrode PE2. For example, the second light-emitting layer EL2 may include an organic light-emitting material which emits green light. The third light-emitting layer EL3 may be arranged on the third pixel electrode PE3. For example, the third light-emitting layer EL3 may include an organic light-emitting material which emits blue light.

The common electrode CE may be arranged on the first to third light-emitting layers EL1, EL2, and EL3. In an embodiment, the common electrode CE may include a metal, an alloy, a conductive metal oxide, a reflective metal, a transparent conductive material, and/or the like. For example, the common electrode CE may include gold (Au), silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), calcium (Ca), barium (Ba), magnesium (Mg), palladium (Pd), neodymium (Nd), iridium (Ir), lithium (Li), titanium (Ti), tantalum (Ta), platinum (Pt), scandium (Sc), indium tin oxide (ITO), indium zinc oxide (IZO), and/or the like. These may be used alone or in combination with each other. In addition, the common electrode CE may be formed as a single layer or as multiple layers. For example, the common electrode CE may be a semi-transmissive electrode.

The encapsulation layer ENC may be arranged on the common electrode CE. The encapsulation layer ENC may prevent or reduce oxygen and/or moisture from penetrating into the first to third light-emitting layers EL1, EL2, and EL3. In an embodiment, the encapsulation layer ENC may have a structure in which inorganic layers and organic layers are alternately stacked with each other.

A cholesteric liquid crystal layer CLC may be arranged on the encapsulation layer ENC. The cholesteric liquid crystal layer CLC may include the first cholesteric liquid crystal layer CLC1, the second cholesteric liquid crystal layer CLC2, and the third cholesteric liquid crystal layer CLC3. The cholesteric liquid crystal layer CLC may include cholesteric liquid crystals. In an embodiment, the cholesteric liquid crystal layer CLC may include a chiral dopant which induces a periodic helical structure. The cholesteric liquid crystal may have a helical structure according to helical characteristics of the chiral dopant. Optical properties of the cholesteric liquid crystal layer CLC may be determined according to a rotation direction of the helical structure of the cholesteric liquid crystal including the chiral dopant.

The first cholesteric liquid crystal layer CLC1 may be arranged on the encapsulation layer ENC and may overlap the first light-emitting layer EL1 in a plan view. The first cholesteric liquid crystal layer CLC1 may selectively reflect light. In an embodiment, the first cholesteric liquid crystal layer CLC1 may selectively reflect red light.

The second cholesteric liquid crystal layer CLC2 may be arranged on the encapsulation layer ENC and may overlap the second light-emitting layer EL2 in a plan view. The second cholesteric liquid crystal layer CLC2 may selectively reflect light. In an embodiment, the second cholesteric liquid crystal layer CLC2 may selectively reflect green light.

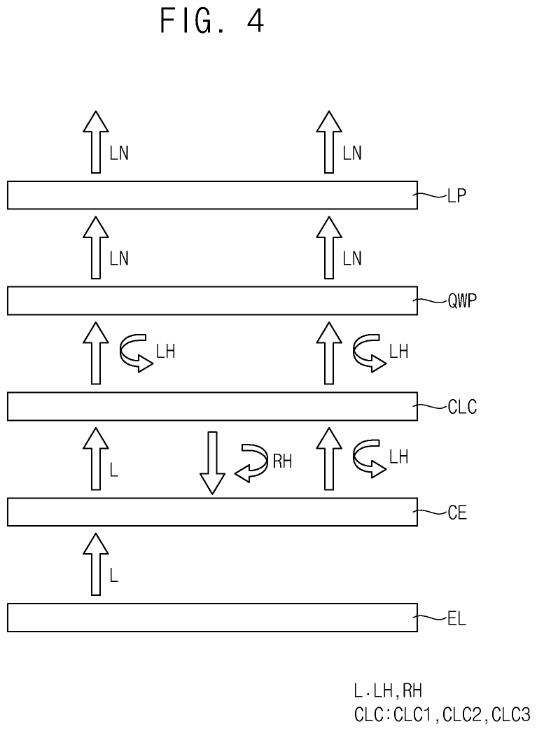

The third cholesteric liquid crystal layer CLC3 may be arranged on the encapsulation layer ENC and may overlap the third light-emitting layer EL3 in a plan view. The third cholesteric liquid crystal layer CLC3 may selectively reflect light. In an embodiment, the third cholesteric liquid crystal layer CLC3 may selectively reflect blue light. Detailed descriptions of the first to third cholesteric liquid crystal layers CLC1, CLC2, and CLC3 will be described later with reference to FIG. 4.

The overcoat layer OC may be arranged on the encapsulation layer ENC and may sufficiently contain the first to third cholesteric liquid crystal layers CLC1, CLC2, and CLC3 to predefined areas. The overcoat layer OC may compensate for a step on a lower surface to have a substantially flat upper surface. In an embodiment, the overcoat layer OC may include an organic insulating material. For example, the overcoat layer OC may include photoresist, polyacrylic resin, polyimide resin, acrylic resin, epoxy resin, acrylate resin, and/or the like. These may be used alone or in combination with each other.

The sensing layer SL may be arranged on the overcoat layer OC. The sensing layer SL may sense a user's touch. In an embodiment, the sensing layer SL may have a structure in which touch electrodes and touch insulating layers are stacked with each other.

The 1-1 light blocking pattern BM1-1 may be arranged on the sensing layer SL and may overlap the pixel defining layer PDL in a plan view. Openings respectively corresponding to the first to third pixel openings OP1, OP2, and OP3 may be defined in the 1-1 light blocking pattern BM1-1.

In an embodiment, the 1-1 light blocking pattern BM1-1 may be arranged in a layer on the cholesteric liquid crystal layer CLC. Specifically, the 1-1 light blocking pattern BM1-1 may be arranged in a layer between the cholesteric liquid crystal layer CLC and the cover window WIN. The 1-1 light blocking pattern BM1-1 may also be arranged in a plurality of layers between the cholesteric liquid crystal layer CLC and the cover window WIN. The 1-1 light blocking pattern BM1-1 may include a light blocking material and may block a portion of light emitted from the first to third light-emitting layers EL1, EL2, and EL3. Accordingly, the 1-1 narrow viewing angle pixel NPX1-1, the 2-1 narrow viewing angle pixel NPX2-1, and the 3-1 narrow viewing angle pixel NPX3-1 may have their viewing angles controlled through the 1-1 light blocking pattern BM1-1. For example, as the 1-1 light blocking pattern BM1-1 is arranged farther away from the first to third light-emitting layers EL1, EL2, and EL3 along the third direction DR3, the viewing angle may decrease, along with luminance in a side view. As a result, the display device DD may be driven in the private mode by controlling the viewing angle through the 1-1 light blocking pattern BM1-1.

The polarizer POL may be arranged on the sensing layer SL and may be arranged in the openings defined in the 1-1 light blocking pattern BM1-1. Specifically, the polarizer POL may overlap the light-emitting layer EL and the cholesteric liquid crystal layer CLC in a plan view. The polarizer POL may include a retardation plate QWP and a linear polarizer LP.

The retardation plate QWP may be arranged on the sensing layer SL. The retardation plate QWP may convert incident light of linear polarization into circular polarization or may convert incident light of circular polarization into linear polarization. In an embodiment, the retardation plate QWP may be a quarter wave plate.

The linear polarizer LP may be arranged on the retardation plate QWP. The linear polarizer LP may transmit light matching a polarization axis and may absorb light not matching the polarization axis.

The cover window WIN may be arranged on the linear polarizer LP. The cover window WIN may protect a display panel of the display device DD and may have light transmittance. For example, the cover window WIN may include a polymer material, a glass thin film, or the like.

FIG. 4 is a view illustrating a movement path of light in the display device according to an embodiment.

Referring to FIG. 4, light L emitted from the light-emitting layer EL may include left-handed circularly polarized light LH and right-handed circularly polarized light RH. Here, the left-handed circularly polarized light LH may mean light in which an electric field rotates counterclockwise as viewed in a light propagation direction, and the right-handed circularly polarized light RH may mean light in which an electric field rotates clockwise as viewed in the light propagation direction. In an embodiment, the first light-emitting layer EL1 may emit left-handed circularly polarized red light and right-handed circularly polarized red light, the second light-emitting layer EL2 may emit left-handed circularly polarized green light and right-handed circularly polarized green light, and the third light-emitting layer EL3 may emit left-handed circularly polarized blue light and right-handed circularly polarized blue light. The light L including the left-handed circularly polarized light LH and the right-handed circularly polarized light RH emitted from the light-emitting layer EL may pass through the common electrode CE.

The cholesteric liquid crystal layer CLC may transmit one of left-handed circularly polarized light LH and right-handed circularly polarized light RH and may reflect the other. That is, the cholesteric liquid crystal layer CLC may selectively reflect one of the left-handed circularly polarized light LH and the right-handed circularly polarized light RH. As illustrated in FIG. 4, in the following description of a light propagation path, it is assumed that the cholesteric liquid crystal layer CLC transmits the left-handed circularly polarized light LH and reflects the right-handed circularly polarized light RH.

In an embodiment, the first cholesteric liquid crystal layer CLC1 may transmit left-handed circularly polarized red light of the red light emitted from the first light-emitting layer EL1 and may reflect right-handed circularly polarized red light toward the common electrode CE. The second cholesteric liquid crystal layer CLC2 may transmit left-handed circularly polarized green light of the green light emitted from the second light-emitting layer EL2 and may reflect right-handed circularly polarized green light toward the common electrode CE. The third cholesteric liquid crystal layer CLC3 may transmit left-handed circularly polarized blue light of the blue light emitted from the third light-emitting layer EL3 and may reflect right-handed circularly polarized blue light toward the common electrode CE.

The common electrode CE may reflect right-handed circularly polarized red light that is incident on the common electrode CE due to selective reflection by the first cholesteric liquid crystal layer CLC1. The reflection at the common electrode CE is a fixed-end reflection, so that a phase may change by 180 degrees. Accordingly, the right-handed circularly polarized red light incident on the common electrode CE may be converted into left-handed circularly polarized red light.

The common electrode CE may reflect right-handed circularly polarized green light that is incident on the common electrode CE due to selective reflection by the second cholesteric liquid crystal layer CLC2. The reflection at the common electrode CE is a fixed-end reflection, so that a phase may change by 180 degrees. Accordingly, the right-handed circularly polarized green light incident on the common electrode CE may be converted into left-handed circularly polarized green light.

The common electrode CE may reflect right-handed circularly polarized blue light that is incident on the common electrode CE due to selective reflection by the third cholesteric liquid crystal layer CLC3. The reflection at the common electrode CE is a fixed-end reflection, so that a phase may change by 180 degrees. Accordingly, the right-handed circularly polarized blue light incident on the common electrode CE may be converted into left-handed circularly polarized blue light.

As a result, both the left-handed circularly polarized light LH and the right-handed circularly polarized light RH included in the light L emitted from the light-emitting layer EL may pass through the cholesteric liquid crystal layer CLC. Accordingly, the light L emitted from the light-emitting layer EL may pass through the cholesteric liquid crystal layer CLC substantially without loss.

The left-handed circularly polarized light LH may be converted into linear polarization LN in the retardation plate QWP. In an embodiment, in case that the retardation plate QWP is a quarter wave plate, the retardation plate QWP may change a phase of incident light by 90 degrees to convert circular polarization into linear polarization.

In case that the cholesteric liquid crystal layer CLC is not included, only the left-handed circularly polarized light LH among the light L emitted from the light-emitting layer EL may pass through the linear polarizer LP, and the right-handed circularly polarized light RH may be absorbed by the linear polarizer LP. However, in case that the cholesteric liquid crystal layer CLC is included, the right-handed circularly polarized light RH may be incident on the common electrode CE, converted into the left-handed circularly polarized light LH, and reflected, so that all of the light L emitted from the light-emitting layer EL may pass through the linear polarizer LP. Accordingly, light efficiency may be improved.

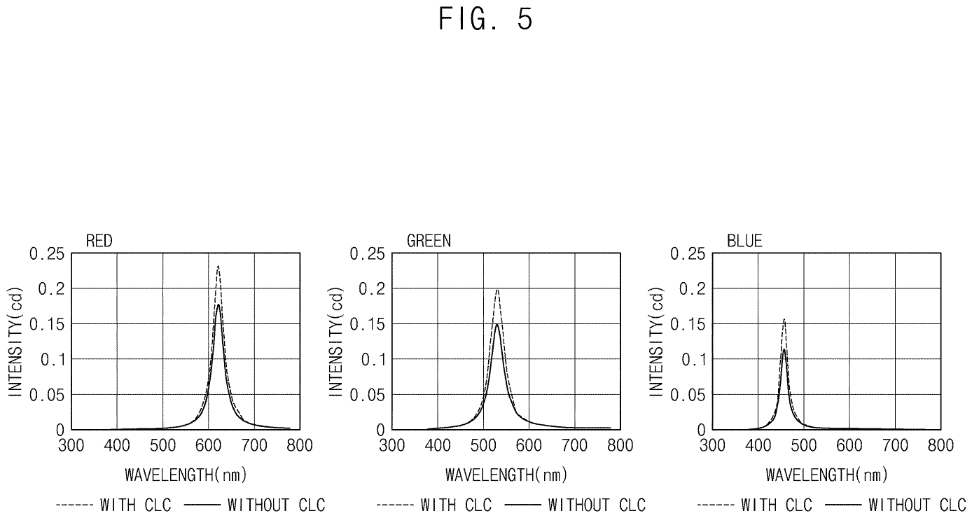

FIG. 5 is a view illustrating a luminance improvement effect of the display device according to an embodiment.

FIG. 5 illustrates graphs comparing luminous intensity of a display device capable of controlling the viewing angle which does not include the cholesteric liquid crystal layer (hereinafter, a conventional display device) and luminous intensity of the display device DD according to an embodiment capable of controlling the viewing angle which includes the cholesteric liquid crystal layer, with respect to red light, green light, and blue light. Hereinafter, a representative wavelength of the red light is about 630 nm, a representative wavelength of the green light is about 530 nm, and a representative wavelength of the blue light is about 470 nm.

Table 1 below is a table summarizing maximum luminous intensity values of the conventional display device of FIG. 5 and maximum luminous intensity values of the display device DD according to the embodiment, with respect to red light, green light, and blue light.

TABLE 1

| Light Color | Red | Green | Blue |
|---|---|---|---|
| With CLC (cd) | 0.23 | 0.20 | 0.16 |
| Without CLC (cd) | 0.18 | 0.15 | 0.11 |
| Increase (%) | 30.7% | 34.0% | 38.2% |

Referring to FIG. 5 and Table 1, in case of the display device DD according to the embodiment compared with the conventional display device, a distribution of luminous intensity became narrower and the luminous intensity increased in representative wavelength bands of red light, green light, and blue light, respectively. Accordingly, a color shift might be prevented or reduced. In addition, the luminous intensity of the display device DD according to the embodiment increased by about 30.7% for red light, about 34.0% for green light, and about 38.2% for blue light compared with the conventional display device. As a result, the luminous intensity had an increased value of at least about 30% or more compared with the conventional display device.

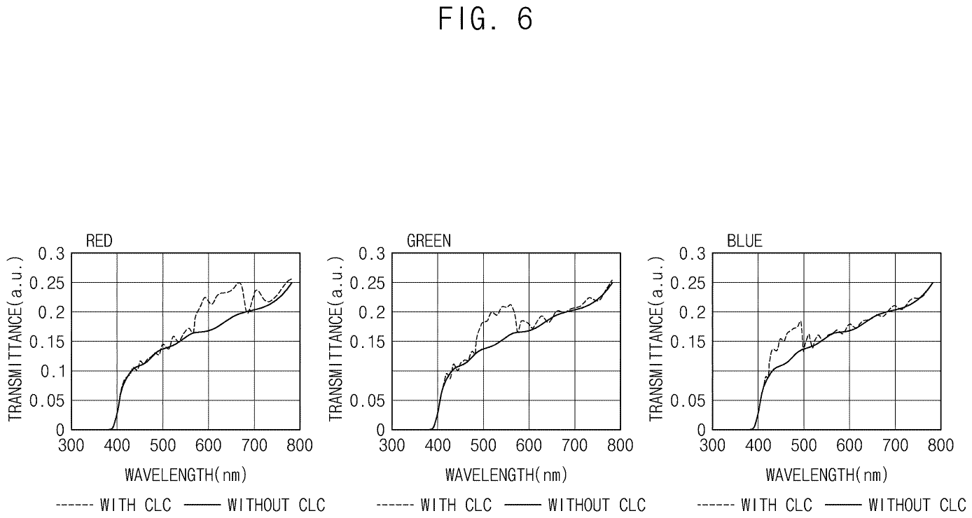

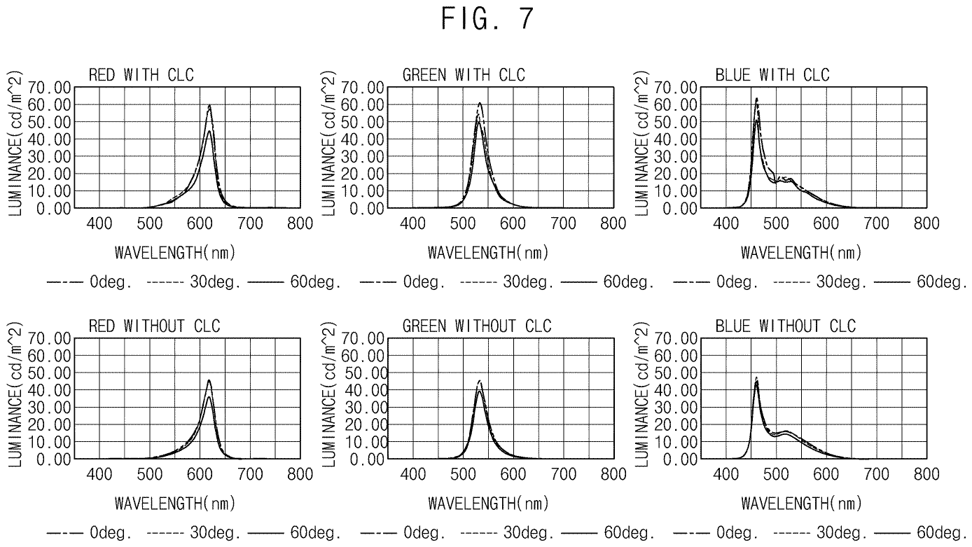

FIG. 6 is a view illustrating a transmittance improvement effect of the display device according to an embodiment. FIG. 7 is a view illustrating a luminance improvement effect of the display device according to an embodiment.

FIG. 6 illustrates graphs comparing transmittance of the conventional display device and transmittance of the display device DD according to the embodiment, with respect to red light, green light, and blue light.

Referring to FIG. 6, in case of the display device DD according to the embodiment compared with the conventional display device, the display device DD had greatly increased transmittance values in representative wavelength bands of red light, green light, and blue light, respectively. Accordingly, as described with reference to FIG. 4, the cholesteric liquid crystal layer CLC selectively reflected light and increased transmittance.

FIG. 7 illustrates graphs comparing luminance of the conventional display device and luminance of the display device DD according to the embodiment, with respect to red light, green light, and blue light. Table 2 below is a table summarizing increase rates of maximum luminance values of the display device DD according to the embodiment compared with maximum luminance values of the conventional display device of FIG. 7, with respect to viewing angles.

TABLE 2

| Viewing Angle | 0 deg. | 30 deg. | 60 deg. |
|---|---|---|---|
| Red | 30.5% | 26.8% | 23.5% |
| Green | 34.9% | 19.9% | 26.3% |
| Blue | 40.9% | 32.4% | 17.0% |

Referring to FIG. 7 and Table 2, in case of the display device DD according to the embodiment compared with the conventional display device, maximum luminance values of red light, green light, and blue light overall increased regardless of viewing angles.

Specifically, in case of the display device DD according to the embodiment compared with the conventional display device, maximum luminance values of red light according to viewing angles increased by about 30.5% at 0°, about 26.8% at 30°, and about 23.5% at 60°. Maximum luminance values of green light according to viewing angles increased by about 34.9% at 0°, about 19.9% at 30°, and about 26.3% at 60°. Maximum luminance values of blue light according to viewing angles increased by about 40.9% at 0°, about 32.4% at 30°, and about 17.0% at 60°. In addition, maximum luminance values of red light, green light, and blue light all increased most dramatically at 0° viewing angle (standing squarely in front of the display). The maximum luminance values of red light and blue light increased the least at 60° viewing angle, and the maximum luminance value of green light increased the least at 30° viewing angle. In case of the display device DD according to the embodiment, the luminance values always increased compared with the conventional display device regardless of viewing angles.

As a result, the display device DD according to the embodiment had improved values of luminous intensity, transmittance, and luminance compared with the conventional display device by including the cholesteric liquid crystal layer CLC.

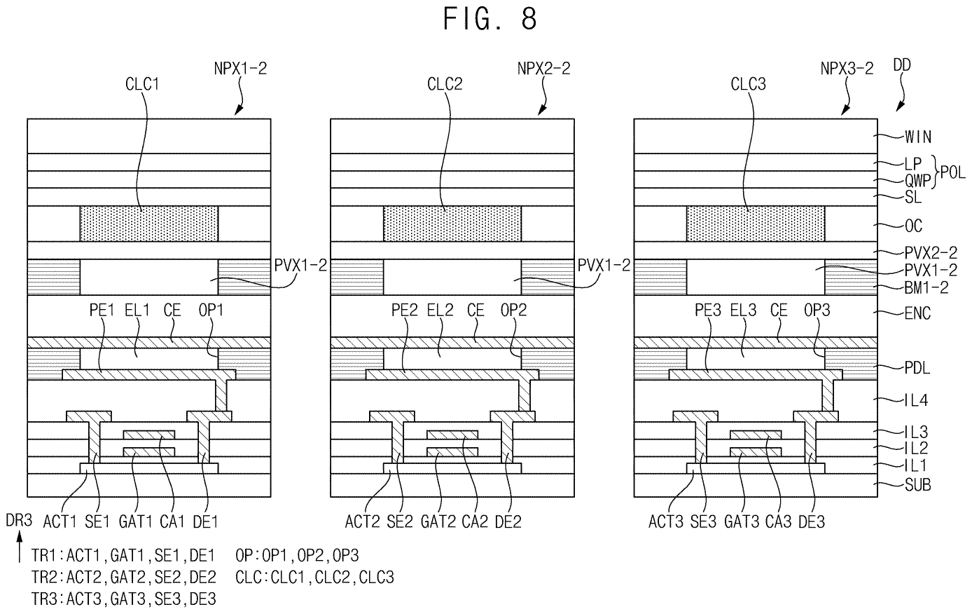

FIG. 8 is a cross-sectional view illustrating another embodiment of the narrow viewing angle pixels included in the display device of FIG. 2.

Referring to FIG. 8, a 1-2 narrow viewing angle pixel NPX1-2, a 2-2 narrow viewing angle pixel NPX2-2, and a 3-2 narrow viewing angle pixel NPX3-2 may be substantially the same as the display device DD described above with reference to FIG. 3, except for the presence of a 1-2 light blocking pattern BM1-2, a 1-2 passivation layer PVX1-2, and a 2-2 passivation layer PVX2-2.

The 1-2 light blocking pattern BM1-2 may be arranged on the encapsulation layer ENC and may overlap the pixel defining layer PDL in a plan view. Openings respectively corresponding to the first to third pixel openings OP1, OP2, and OP3 may be defined in the 1-2 light blocking pattern BM1-2.

In an embodiment, the 1-2 light blocking pattern BM1-2 may be arranged in a layer below the cholesteric liquid crystal layer CLC. Specifically, the 1-2 light blocking pattern BM1-2 may be arranged in a layer between the cholesteric liquid crystal layer CLC and the light-emitting layer EL. The 1-2 light blocking pattern BM1-2 may also be arranged in a plurality of layers between the cholesteric liquid crystal layer CLC and the light-emitting layer EL. The 1-2 light blocking pattern BM1-2 may include a light blocking material and may block a portion of light emitted from the first to third light-emitting layers EL1, EL2, and EL3. Accordingly, the 1-2 narrow viewing angle pixel NPX1-2, the 2-2 narrow viewing angle pixel NPX2-2, and the 3-2 narrow viewing angle pixel NPX3-2 may have their viewing angles controlled through the 1-2 light blocking pattern BM1-2. For example, as the 1-2 light blocking pattern BM1-2 is arranged closer to the first to third light-emitting layers EL1, EL2, and EL3, a viewing angle may increase along with luminance in a side view. As a result, the display device DD may be driven in the private mode by controlling the viewing angle through the 1-2 light blocking pattern BM1-2.

The 1-2 passivation layer PVX1-2 may be arranged on the encapsulation layer ENC and may be arranged in the openings defined in the 1-2 light blocking pattern BM1-2. In an embodiment, the 1-2 passivation layer PVX1-2 may include an organic insulating material. For example, the 1-2 passivation layer PVX1-2 may include a photoresist, a polyacrylic resin, a polyimide resin, an acrylic resin, and/or the like. However, embodiments are not necessarily limited thereto. For example, the 1-2 passivation layer PVX1-2 may include an inorganic insulating material, such as silicon oxide (SiOₓ), silicon nitride (SiNₓ), silicon oxynitride (SiOₓN_{y}), and/or the like. For example, the 1-2 passivation layer PVX1-2 may have a multi-layer structure including one or more organic insulating layers and/or one or more inorganic insulating layers.

The 2-2 passivation layer PVX2-2 may be arranged on the 1-2 passivation layer PVX1-2. In an embodiment, the 2-2 passivation layer PVX2-2 may include an inorganic insulating material. For example, the 2-2 passivation layer PVX2-2 may include silicon oxide (SiOₓ), silicon nitride (SiNₓ), silicon oxynitride (SiOₓN_{y}), and/or the like. However, embodiments are not necessarily limited thereto. For example, the 2-2 passivation layer PVX2-2 may include an organic insulating material, such as a photoresist, a polyacrylic resin, a polyimide resin, an acrylic resin, and/or the like. For example, the 2-2 passivation layer PVX2-2 may have a multi-layer structure including one or more organic insulating layers and/or one or more inorganic insulating layers.

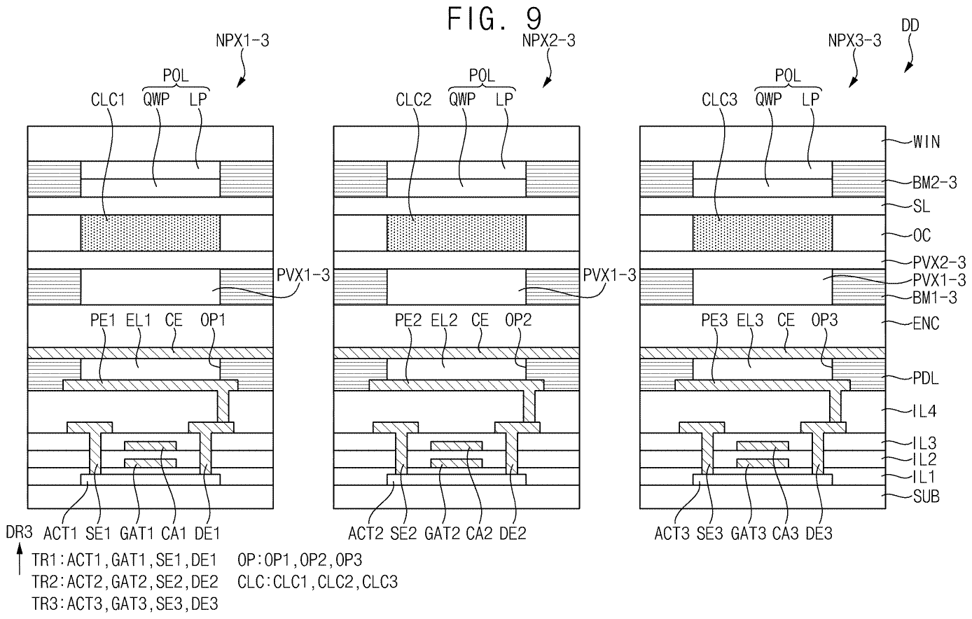

FIG. 9 is a cross-sectional view illustrating still another embodiment of the narrow viewing angle pixels included in the display device of FIG. 2.

Referring to FIG. 9, a 1-3 narrow viewing angle pixel NPX1-3, a 2-3 narrow viewing angle pixel NPX2-3, and a 3-3 narrow viewing angle pixel NPX3-3 may be substantially the same as the display device DD described above with reference to FIG. 3, except for a 1-3 light blocking pattern BM1-3, a 1-3 passivation layer PVX1-3, a 2-3 passivation layer PVX2-3, and a 2-3 light blocking pattern BM2-3.

The 1-3 light blocking pattern BM1-3 may be arranged on the encapsulation layer ENC and may overlap the pixel defining layer PDL in a plan view. Openings respectively corresponding to the first to third pixel openings OP1, OP2, and OP3 may be defined in the 1-3 light blocking pattern BM1-3.

In an embodiment, the 1-3 light blocking pattern BM1-3 may be arranged in a layer below the cholesteric liquid crystal layer CLC. Specifically, the 1-3 light blocking pattern BM1-3 may be arranged in a layer between the cholesteric liquid crystal layer CLC and the light-emitting layer EL. The 1-3 light blocking pattern BM1-3 may also be arranged in a plurality of layers between the cholesteric liquid crystal layer CLC and the light-emitting layer EL. The 1-3 light blocking pattern BM1-3 may include a light blocking material and may block a portion of light emitted from the first to third light-emitting layers EL1, EL2, and EL3. Accordingly, the 1-3 narrow viewing angle pixel NPX1-3, the 2-3 narrow viewing angle pixel NPX2-3, and the 3-3 narrow viewing angle pixel NPX3-3 may have their viewing angles controlled through the 1-3 light blocking pattern BM1-3. For example, as the 1-3 light blocking pattern BM1-3 is arranged closer to the first to third light-emitting layers EL1, EL2, and EL3, the viewing angle may increase along with luminance in the side view.

The 1-3 passivation layer PVX1-3 may be arranged on the encapsulation layer ENC and may be arranged in the openings defined in the 1-3 light blocking pattern BM1-3. In an embodiment, the 1-3 passivation layer PVX1-3 may include an organic insulating material. For example, the 1-3 passivation layer PVX1-3 may include a photoresist, a polyacrylic resin, a polyimide resin, an acrylic resin, and/or the like. However, embodiments are not necessarily limited thereto. For example, the 1-3 passivation layer PVX1-3 may include an inorganic insulating material, such as silicon oxide (SiOₓ), silicon nitride (SiNₓ), silicon oxynitride (SiOₓN_{y}), and/or the like. For example, the 1-3 passivation layer PVX1-3 may have a multi-layer structure including one or more organic insulating layers and/or one or more inorganic insulating layers.

The 2-3 passivation layer PVX2-3 may be arranged on the 1-3 passivation layer PVX1-3. In an embodiment, the 2-3 passivation layer PVX2-3 may include an inorganic insulating material. For example, the 2-3 passivation layer PVX2-3 may include silicon oxide (SiOₓ), silicon nitride (SiNₓ), silicon oxynitride (SiOₓN_{y}), and/or the like. However, embodiments are not necessarily limited thereto. For example, the 2-3 passivation layer PVX2-3 may include an organic insulating material, such as a photoresist, a polyacrylic resin, a polyimide resin, an acrylic resin, and/or the like. For example, the 2-3 passivation layer PVX2-3 may have a multi-layer structure including one or more organic insulating layers and/or one or more inorganic insulating layers.

The 2-3 light blocking pattern BM2-3 may be arranged on the sensing layer SL and may overlap the pixel defining layer PDL and the 1-3 light blocking pattern BM1-3 in a plan view. Openings respectively corresponding to the first to third pixel openings OP1, OP2, and OP3 may be defined in the 2-3 light blocking pattern BM2-3.

In an embodiment, the 2-3 light blocking pattern BM2-3 may be arranged in a layer on the cholesteric liquid crystal layer CLC. Specifically, the 2-3 light blocking pattern BM2-3 may be arranged in a layer between the cholesteric liquid crystal layer CLC and the cover window WIN. The 2-3 light blocking pattern BM2-3 may include a light blocking material and may block a portion of light emitted from the first to third light-emitting layers EL1, EL2, and EL3. Accordingly, the 1-3 narrow viewing angle pixel NPX1-3, the 2-3 narrow viewing angle pixel NPX2-3, and the 3-3 narrow viewing angle pixel NPX3-3 may have their viewing angles controlled through the 2-3 light blocking pattern BM2-3. For example, as the 2-3 light blocking pattern BM2-3 is arranged farther from the first to third light-emitting layers EL1, EL2, and EL3 along the third direction DR3, the viewing angle may decrease along with luminance in the side view.

In an embodiment, the first to third cholesteric liquid crystal layers CLC1, CLC2, and CLC3 may be arranged between a layer including the 1-3 light blocking pattern BM1-3 and a layer including the 2-3 light blocking pattern BM2-3.

As a result, the display device DD may be driven in the private mode by controlling the viewing angle through the 1-3 light blocking pattern BM1-3 and the 2-3 light blocking pattern BM2-3.

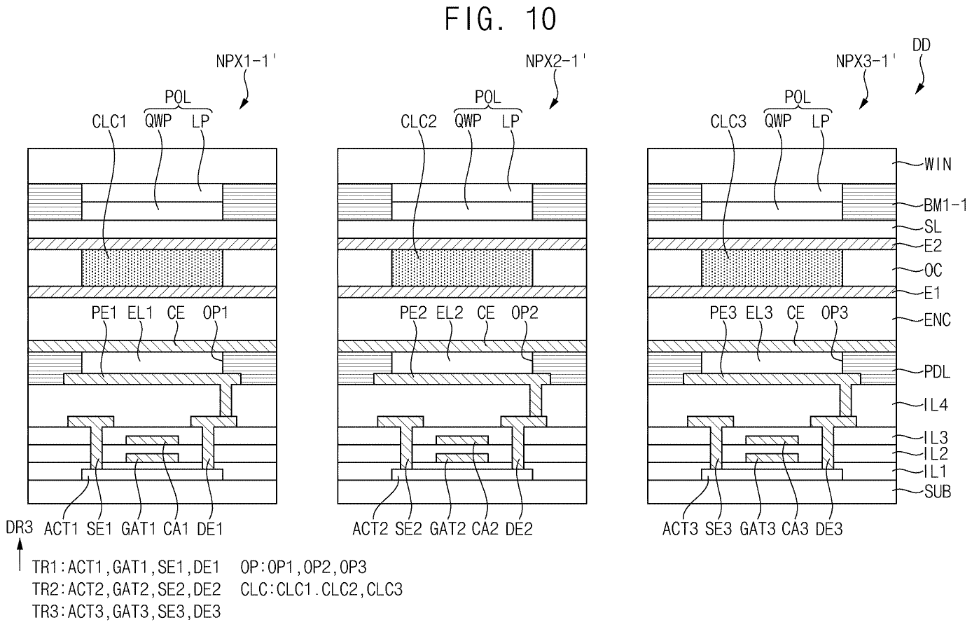

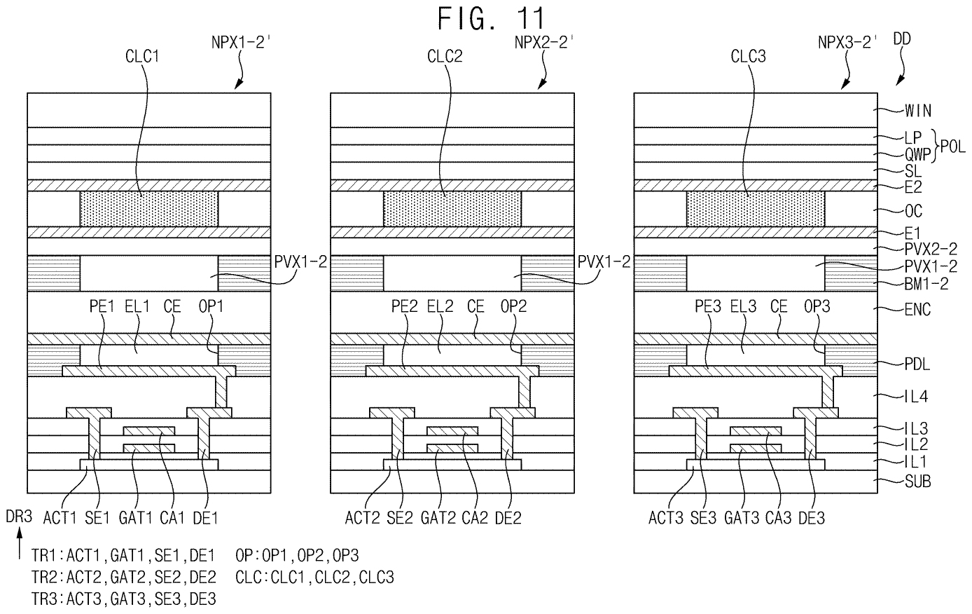

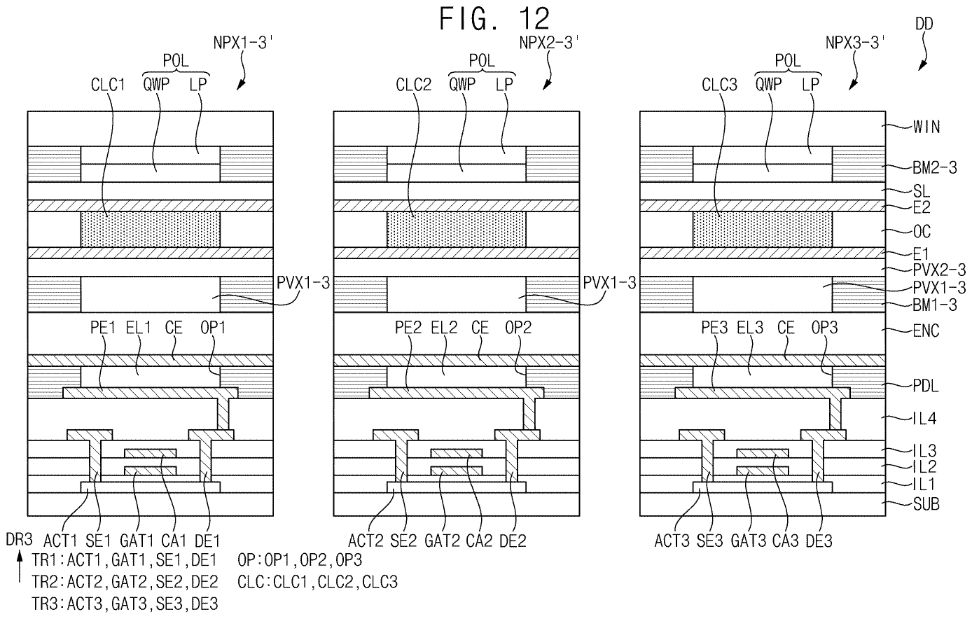

FIGS. 10 to 12 are cross-sectional views illustrating yet another embodiment of the narrow viewing angle pixels included in the display device of FIG. 2.

Referring to FIGS. 10 to 12, a 1-1′ narrow viewing angle pixel NPX1-1′, a 2-1′ narrow viewing angle pixel NPX2-1′, a 3-1′ narrow viewing angle pixel NPX3-1′, a 1-2′ narrow viewing angle pixel NPX1-2′, a 2-2′ narrow viewing angle pixel NPX2-2′, a 3-2′ narrow viewing angle pixel NPX3-2′, a 1-3′ narrow viewing angle pixel NPX1-3′, a 2-3′ narrow viewing angle pixel NPX2-3′, and a 3-3′ narrow viewing angle pixel NPX3-3′ may be substantially the same as the display device DD described above with reference to FIGS. 3, 8, and 9, except for a first electrode E1 and a second electrode E2.

In an embodiment, the first electrode E1 may be arranged under the first to third cholesteric liquid crystal layers CLC1, CLC2, and CLC3 and may directly contact the first to third cholesteric liquid crystal layers CLC1, CLC2, and CLC3. In an embodiment, the second electrode E2 may be arranged on the first to third cholesteric liquid crystal layers CLC1, CLC2, and CLC3 and may directly contact the first to third cholesteric liquid crystal layers CLC1, CLC2, and CLC3. In an embodiment, the first electrode E1 and the second electrode E2 may include a transparent conductive material. For example, the first electrode E1 and the second electrode E2 may include indium tin oxide ITO, indium zinc oxide IZO, and/or the like.

If there is no voltage difference between the first electrode E1 and the second electrode E2, the first, second, and third cholesteric liquid crystal layers CLC1, CLC2, and CLC3 may not selectively reflect either left-handed circularly polarized light or right-handed circularly polarized light. Accordingly, light efficiency in the private mode may be maintained without any increase or decrease.

If there is a voltage difference between the first electrode E1 and the second electrode E2, the first, second, and third cholesteric liquid crystal layers CLC1, CLC2, and CLC3 may selectively reflect either left-handed circularly polarized light or right-handed circularly polarized light. Accordingly, light efficiency in the private mode may be improved.

As a result, luminance of the general mode and the private mode of the display device DD may be controlled by turning ON/OFF the voltage applied to each of the first, second, and third cholesteric liquid crystal layers CLC1, CLC2, and CLC3 through the first electrode E1 and the second electrode E2.

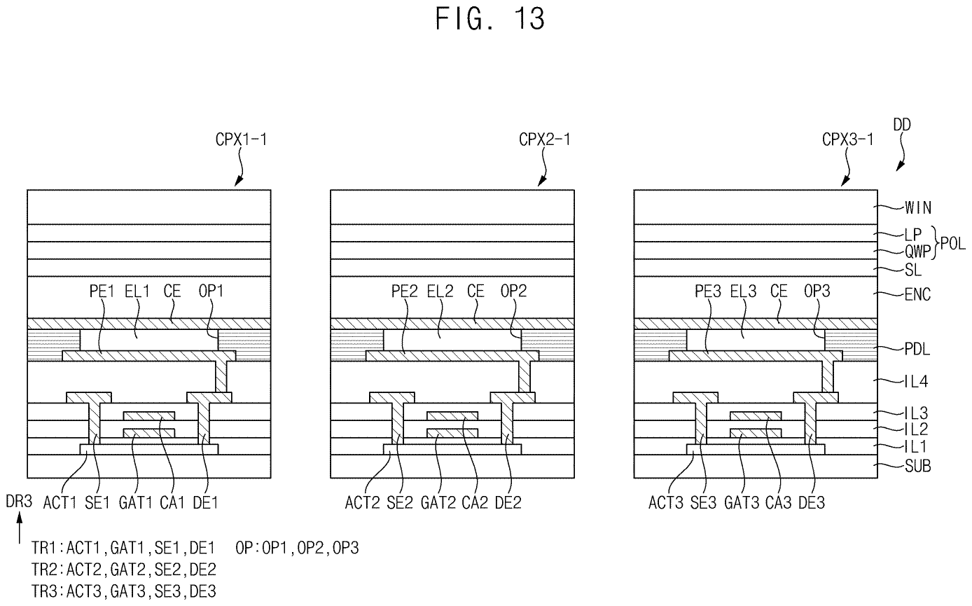

FIG. 13 is a cross-sectional view illustrating one embodiment of general pixels included in the display device of FIG. 2.

Referring to FIG. 13, a 1-1 general pixel CPX1-1, a 2-1 general pixel CPX2-1, and a 3-1 general pixel CPX3-1 may be substantially the same as the display device DD described above with reference to FIG. 3, except that they do not include the first to third cholesteric liquid crystal layers CLC1, CLC2, and CLC3, the overcoat layer OC, and the 1-1 light blocking pattern BM1-1.

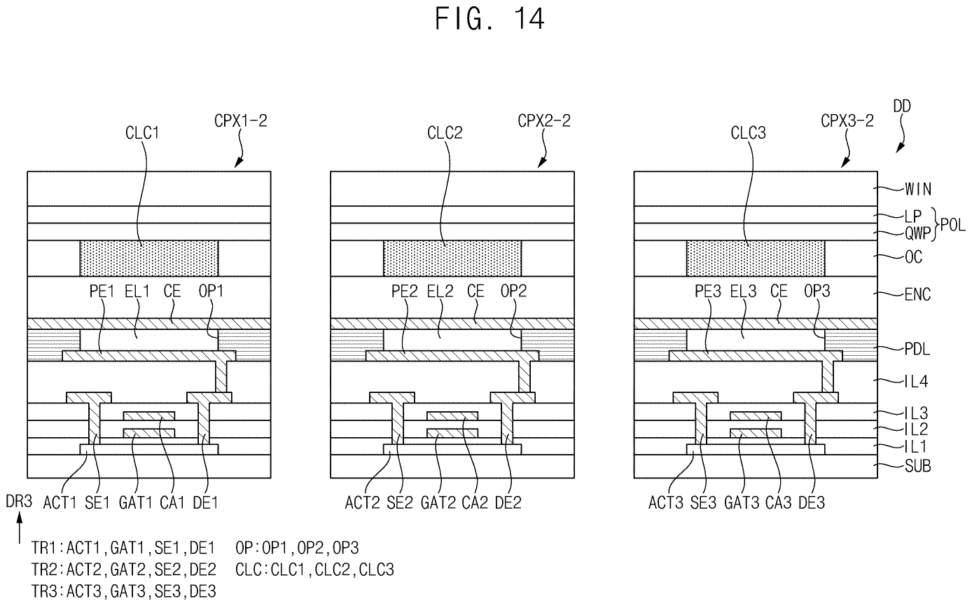

FIG. 14 is a cross-sectional view illustrating another embodiment of the general pixels included in the display device of FIG. 2.

Referring to FIG. 14, a 1-2 general pixel CPX1-2, a 2-2 general pixel CPX2-2, and a 3-2 general pixel CPX3-2 may be substantially the same as the display device DD described above with reference to FIG. 3, except that they do not include the 1-1 light blocking pattern BM1-1.

The 1-2 general pixel CPX1-2, the 2-2 general pixel CPX2-2, and the 3-2 general pixel CPX3-2 may include the first to third cholesteric liquid crystal layers CLC1, CLC2, and CLC3, respectively. The first to third cholesteric liquid crystal layers CLC1, CLC2, and CLC3 may selectively reflect one of right-handed circularly polarized light and left-handed circularly polarized light emitted from the first to third light-emitting layers EL1, EL2, and EL3. The common electrode CE may reflect light which is incident on the common electrode CE due to selective reflection by the first to third cholesteric liquid crystal layers CLC1, CLC2, and CLC3, thereby changing a phase of the light so that the light may pass through the polarizer POL. Accordingly, light efficiency in the general mode may also be improved.

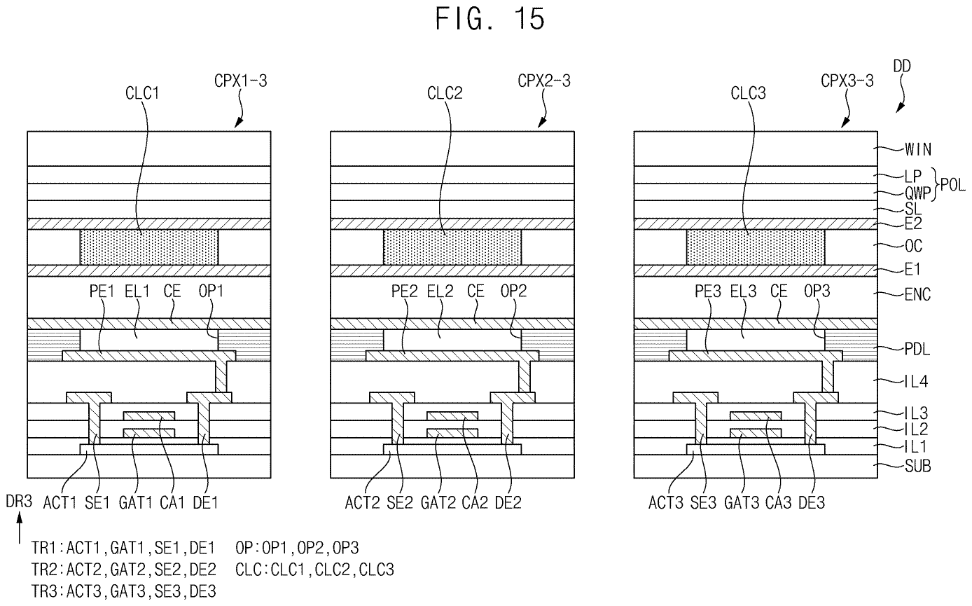

FIG. 15 is a cross-sectional view illustrating still another embodiment of the general pixels included in the display device of FIG. 2.

Referring to FIG. 15, a 1-3 general pixel CPX1-3, a 2-3 general pixel CPX2-3, and a 3-3 general pixel CPX3-3 may be substantially the same as the display device DD described above with reference to FIG. 10, except that they do not include the 1-1 light blocking pattern BM1-1.

The 1-3 general pixel CPX1-3, the 2-3 general pixel CPX2-3, and the 3-3 general pixel CPX3-3 may include the first to third cholesteric liquid crystal layers CLC1, CLC2, and CLC3, the first electrode E1, and the second electrode E2.

In case that there is no voltage difference between the first electrode E1 and the second electrode E2, the first to third cholesteric liquid crystal layers CLC1, CLC2, and CLC3 may not selectively reflect either left-handed circularly polarized light or right-handed circularly polarized light. Accordingly, light efficiency in the general mode may be maintained without increase or decrease.

In case that there is a voltage difference between the first electrode E1 and the second electrode E2, the first to third cholesteric liquid crystal layers CLC1, CLC2, and CLC3 may selectively reflect either left-handed circularly polarized light or right-handed circularly polarized light. Accordingly, light efficiency in the general mode may be improved.

As a result, luminance in the general mode may also be controlled by turning ON/OFF the voltage applied to each of the first to third cholesteric liquid crystal layers CLC1, CLC2, and CLC3 through the first electrode E1 and the second electrode E2.

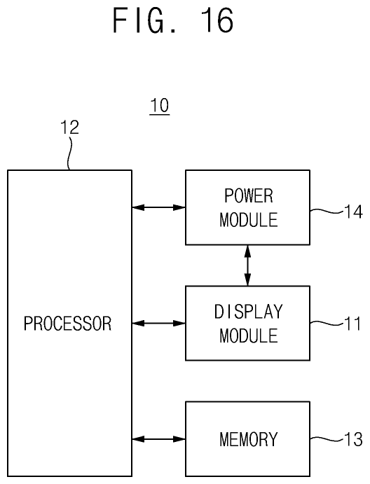

FIG. 16 is a schematic block diagram of an electronic device according to an embodiment.

Referring to FIG. 16, the electronic device 10 according to an embodiment may include a display module 11, a processor 12, a memory 13, and a power module 14.

The processor 12 may control the display device. The processor 12 may include at least one of a central processing unit (CPU), an application processor (AP), a graphic processing unit (GPU), a communication processor (CP), an image signal processor (ISP), and a controller.

Data information necessary for the operation of the processor 12 or the display module 11 may be stored in the memory 13. In a case where the processor 12 executes an application stored in the memory 13, an image data signal and/or an input control signal is transmitted to the display module 11, and the display module 11 may process the received signal and output image information through a display screen.

The power module 14 may include a power supply module such as a power adapter or a battery device, and a power conversion module which converts power supplied by the power supply module to generate power required for the operation of the electronic device 10.

At least one of the components of the electronic device 10 described above may be included in a display device (e.g., the display device DD of FIG. 1) according to the embodiments described above. Some of the individual modules functionally included in a single module may be included in the display device, while others may be provided separately from the display device. For example, the display device may include the display module 11, and the processor 12, the memory 13, and the power module 14 may be provided in the form of other devices in the electronic device 10 other than the display device.

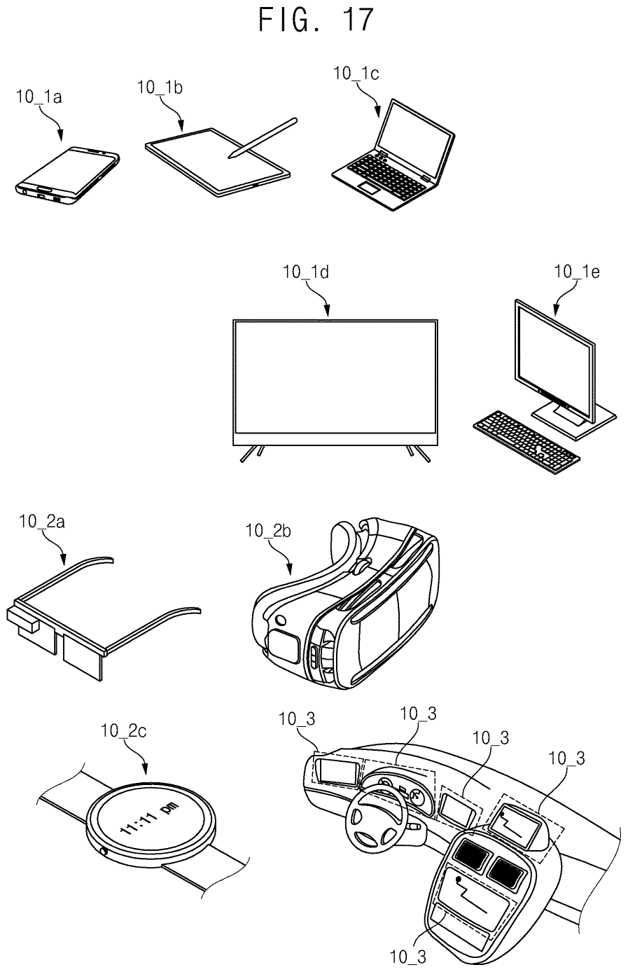

FIG. 17 is a schematic diagram of various electronic devices according to various embodiments.

Referring to FIG. 17, various electronic devices to which display devices according to embodiments (for example, display device DD of FIG. 1) are applied may include not only image display electronic devices such as a smart phone 10_1b, a tablet 10_1b, a laptop 10_1c, a TV 10_1d, and a desk monitor 10_1e, but also wearable electronic devices including display module such as smart glasses 10_2a, a head mounted display 10_2b, and a smart watch 10_2c, and vehicle electronic devices 10_3 including display modules such as a center information display (CID) and a room mirror display arranged on an instrument panel, a center fascia, and a dashboard of an automobile.

The inventive concept may be applied to a display device and an electronic device including the same. For example, the invention may be applied to high-resolution smart phones, mobile phones, smart pads, smart watches, tablets, vehicle navigation systems, televisions, computer monitors, laptops, or the like.

Although the inventive concept has been described with reference to embodiments, it will be understood by those skilled in the art which various modifications and changes may be made therein without departing from the spirit and scope of the invention as set forth in the claims below.

What is claimed is:

1. A display device comprising:
a substrate including emission areas and a non-emission area surrounding the emission areas; and
narrow viewing angle pixels and general pixels arranged in the emission areas,
wherein each of the narrow viewing angle pixels includes:
a light-emitting layer arranged on the substrate and arranged in a pixel opening defined in a pixel defining layer;
a common electrode arranged on the light-emitting layer;
a cholesteric liquid crystal layer including a chiral dopant and overlapping the light-emitting layer;
a light blocking pattern overlapping the pixel defining layer; and
a polarizer arranged on the cholesteric liquid crystal layer.

2. The display device of claim 1, wherein the light blocking pattern is arranged in a layer between the cholesteric liquid crystal layer and a cover window.

3. The display device of claim 1, wherein the light blocking pattern is arranged in a layer between the cholesteric liquid crystal layer and the light-emitting layer.

4. The display device of claim 1, wherein the light blocking pattern includes:
a first light blocking pattern arranged on the common electrode; and
a second light blocking pattern arranged on the first light blocking pattern, and
wherein the cholesteric liquid crystal layer is arranged between a first layer including the first light blocking pattern and a second layer including the second light blocking pattern.

5. The display device of claim 1, wherein the light-emitting layer includes:
a first light-emitting layer that emits red light;
a second light-emitting layer that emits green light; and
a third light-emitting layer that emits blue light,
wherein the cholesteric liquid crystal layer includes:
a first cholesteric liquid crystal layer overlapping the first light-emitting layer in a plan view;
a second cholesteric liquid crystal layer overlapping the second light-emitting layer in a plan view; and
a third cholesteric liquid crystal layer overlapping the third light-emitting layer in a plan view, and
wherein the first cholesteric liquid crystal layer selectively reflects either right-handed circularly polarized red light or left-handed circularly polarized red light, the second cholesteric liquid crystal layer selectively reflects either right-handed circularly polarized green light or left-handed circularly polarized green light, and the third cholesteric liquid crystal layer selectively reflects either right-handed circularly polarized blue light or left-handed circularly polarized blue light.

6. The display device of claim 1, wherein the common electrode changes a phase of light that is reflected from the cholesteric liquid crystal layer so that the light passes through the polarizer.

7. The display device of claim 1, wherein the polarizer includes:
a phase difference plate arranged on the cholesteric liquid crystal layer; and
a linear polarizer arranged on the phase difference plate.

8. The display device of claim 7, wherein the phase difference plate is a quarter wave plate.

9. The display device of claim 1, wherein each of the narrow viewing angle pixels further includes:
a first electrode arranged under the cholesteric liquid crystal layer and contacting the cholesteric liquid crystal layer; and
a second electrode arranged on the cholesteric liquid crystal layer and contacting the cholesteric liquid crystal layer.

10. The display device of claim 9, wherein the first electrode and the second electrode include a transparent conductive material.

11. The display device of claim 1, wherein the general pixels are spaced apart from the narrow viewing angle pixels, and
center points of the general pixels are respectively arranged at vertices of a virtual rectangle centered at a center point of the narrow viewing angle pixel.

12. The display device of claim 1, wherein each of the general pixels includes:
a light-emitting layer arranged on the substrate and arranged in the pixel opening defined in the pixel defining layer;
the common electrode arranged on the light-emitting layer; and
the polarizer arranged on the common electrode.

13. The display device of claim 12, wherein each of the general pixels further includes:
the cholesteric liquid crystal layer including the chiral dopant arranged on the common electrode and overlapping the light-emitting layer in a plan view.

14. The display device of claim 13, wherein each of the general pixels further includes:
a first electrode arranged under the cholesteric liquid crystal layer and contacting the cholesteric liquid crystal layer; and
a second electrode arranged on the cholesteric liquid crystal layer and contacting the cholesteric liquid crystal layer.

15. An electronic device comprising:
a display device including:
a substrate including emission areas and a non-emission area surrounding the emission areas; and
narrow viewing angle pixels and general pixels arranged in the emission areas,
wherein each of the narrow viewing angle pixels includes:
a light-emitting layer arranged on the substrate and arranged in a pixel opening defined in a pixel defining layer;
a common electrode arranged on the light-emitting layer;
a cholesteric liquid crystal layer including a chiral dopant and overlapping the light-emitting layer;
a light blocking pattern overlapping the pixel defining layer; and
a polarizer arranged on the cholesteric liquid crystal layer; and
a processor that controls the display device.

16. The electronic device of claim 15, wherein the light blocking pattern is arranged in a layer between the cholesteric liquid crystal layer and a cover window.

17. The electronic device of claim 15, wherein the light blocking pattern is arranged in a layer between the cholesteric liquid crystal layer and the light-emitting layer.

18. The electronic device of claim 15, wherein the light blocking pattern includes:
a first light blocking pattern arranged on the common electrode; and
a second light blocking pattern arranged on the first light blocking pattern, and
wherein the cholesteric liquid crystal layer is arranged between a first layer including the first light blocking pattern and a second layer including the second light blocking pattern.

19. The electronic device of claim 15, wherein each of the narrow viewing angle pixels further includes:
a first electrode arranged under the cholesteric liquid crystal layer and contacting the cholesteric liquid crystal layer; and
a second electrode arranged on the cholesteric liquid crystal layer and contacting the cholesteric liquid crystal layer.

20. The electronic device of claim 15, wherein the first electrode and the second electrode include a transparent conductive material.
